(19) United States
(12) Patent Application Publication
(10) Pub. No.: US 2020/0333384 A1
(43) Pub. Date: Oct. 22, 2020

(54) METHOD FOR CALCULATING A TRANSIENT OVERVOLTAGE AT A DIRECT CURRENT SENDING END BY TAKING INTO ACCOUNT A DYNAMIC PROCESS OF A CONTROL SYSTEM

(71) Applicants: STATE GRID JIANGSU ELECTRIC POWER CO., LTD., Jiangsu (CN); NORTHEAST ELECTRIC POWER UNIVERSITY, Jilin (CN); STATE GRID CORPORATION OF CHINA, Beijing (CN)

(72) Inventors: Qing Chen, Jiangsu (CN); Haifeng Li, Jiangsu (CN); Houhe Chen, Jiangsu (CN); Changjiang Wang, Jiangsu (CN); Tao Jin, Jiangsu (CN); He Zhang, Jiangsu (CN); Huawei Lu, Jiangsu (CN); Jiagui Tao, Jiangsu (CN); Yu Liu, Jiangsu (CN)

(73) Assignees: STATE GRID JIANGSU ELECTRIC POWER CO., LTD., Jiangsu (CN); NORTHEAST ELECTRIC POWER UNIVERSITY, Jilin (CN); STATE GRID CORPORATION OF CHINA, Beijing (CN)

(21) Appl. No.: 16/538,161

(22) Filed: Aug. 12, 2019

(30) Foreign Application Priority Data
Apr. 17, 2019 (CN) 201910315672.4

(51) Int. Cl. G01R 19/25; H02H 1/00

(52) U.S. Cl. CPC G01R 19/2513; H02H 1/0007

(57) ABSTRACT

Disclosed is a method for calculating a transient overvoltage at a direct current (DC) sending end by taking into account a dynamic process of a control system. First, a first reactive power consumed by a converter station is calculated based on system operation parameters and a DC closed-loop transfer function. Then, a transient voltage change rate is calculated based on the first reactive power and a second reactive power on an alternating current (AC) side. Finally, the transient voltage change rate is iterated to obtain the transient overvoltage. According to the technical solution provided by the embodiments of the present disclosure, the transient overvoltage is determined based on the system operation parameters and the closed-loop transfer function of a DC line, the dynamic process of control parameter change caused by a control action of the control system after a fault occurs can be determined by the closed-loop transfer function of the DC line, whereby the transient overvoltage can be determined.

### CROSS-REFERENCE TO RELATED APPLICATIONS

This U.S. application claims the priority of China patent application No. 201910315672.4 filed on Apr. 17, 2019, disclosure of which is incorporated herein by reference in its entirety.

### TECHNICAL FIELD

Embodiments of the present disclosure relate to the technical field of electric power systems, and in particular, to a method and apparatus for calculating a transient overvoltage at a direct current (DC) sending end by taking into account a dynamic process of a control system, as well as a device and a storage medium.

### BACKGROUND

As ultra- or extra-high voltage DC electric power transmission projects continue to be put into operation, the “strong DC and weak alternating current (AC)” characteristic of the power grid becomes increasingly prominent. While the DC electric power transmission has the advantage of large-capacity and long-distance electric power transmission, it also causes a series of security and stability problems. DC electric power transmission is an electric power transmission mode in which a three-phase AC is rectified to a DC through a converter station, and then the DC is sent to another converter station through a DC electric power transmission line to be inverted into a three-phase AC. The DC electric power transmission system is essentially formed by two converter stations and a DC electric power transmission line. The two converter stations are connected to AC systems at the sending and receiving ends.

In case a fault occurs in the DC electric power transmission system, the safe and stable operation of the AC systems at the sending and receiving ends would be affected. During the system fault period and the fault repair process, the reactive power consumed by the converter and the reactive power generated by the AC systems are subjected to a transient change process, and the reactive power exchanged between the DC line and the AC systems at the sending and receiving ends is also significantly changed, which manifests as an external characteristic of “large-capacity reactive impact load” that is disadvantageous to the system.

At present, scholars at home and abroad have carried out a preliminary research on the mechanism and suppression measures of transient overvoltages of the DC delivery system caused by the AC/DC fault disturbance. However, most of the conventional transient overvoltage calculation methods are qualitative analysis in nature based on system strength indices such as a short-circuit ratio, a multiple-feed short-circuit ratio and the like, as well as AC system equivalence methods that takes into account the system steady-state transmission power. The existing transient overvoltage calculation methods ignore the dynamic process of the DC control parameter change caused by the control action of the DC control system after a fault occurs in the system, resulting in inaccurate over-voltage calculation results.

### SUMMARY

The present disclosure provides a method and apparatus for calculating a transient overvoltage at a DC sending end by taking into account a dynamic process of a control system, as well as a device and a storage medium, which take into account the dynamic process of the control system and so can reflect the actual operation of the system, leading to a more accurate calculation result.

In a first aspect, embodiments according to the present disclosure provide a method for calculating a transient overvoltage at a DC sending end by taking into account a dynamic process of a control system. The method includes the following operations:

calculating a first reactive power consumed by a converter station based on system operation parameters and a DC closed-loop transfer function;

calculating a transient voltage change rate based on the first reactive power and a second reactive power on an AC side; and

iterating the transient voltage change rate to obtain a transient overvoltage.

In a second aspect, embodiments according to the present disclosure further provide an apparatus for calculating a transient overvoltage at a DC sending end by taking into account a dynamic process of a control system. The apparatus includes a first reactive power calculation module, a transient voltage change rate calculation module, and a transient voltage change rate iteration module.

The first reactive power calculation module is configured to calculate a first reactive power consumed by a converter station based on system operation parameters and a DC closed-loop transfer function.

The transient voltage change rate calculation module is configured to calculate a transient voltage change rate based on the first reactive power and a second reactive power on an AC side.

The transient voltage change rate iteration module is configured to iterate the transient voltage change rate to obtain a transient overvoltage.

In a third aspect, embodiments according to the present disclosure further provide a device that includes one or more processors, and a memory configured to store one or more programs.

The one or more programs, when executed by the one or more processors, cause the one or more processors to perform the above method for calculating a transient overvoltage at a DC sending end by taking into account a dynamic process of a control system described in the first aspect.

In a fourth aspect, embodiments according to the present disclosure further provide a computer-readable storage medium configured to store computer programs which, when executed by a processor, perform the above method for calculating a transient overvoltage at a DC sending end by taking into account a dynamic process of a control system described in the first aspect.

Embodiments according to the present disclosure provide a method and apparatus for calculating a transient overvoltage at a DC sending end by taking into account a dynamic process of a control system, as well as a device and a storage medium. First, a first reactive power consumed by a converter station is calculated based on system operation parameters and a DC closed-loop transfer function. Then, a transient voltage change rate is calculated according to the first reactive power and a second reactive power on an AC side. Finally, the transient voltage change rate is iterated to obtain a transient overvoltage. According to the technical solution provided by the embodiments of the present disclosure, the transient overvoltage is determined based on the system operation parameters and the closed-loop transfer function of the DC line, the dynamic process of control parameter change caused by a control action of the control system after a fault occurs can be determined by the closed-loop transfer function of the DC line, whereby the transient overvoltage can be determined. The embodiments take into account the dynamic process of the DC control system, and can reflect actual operation of a DC electric power transmission system, so that the calculation result is more accurate.

### BRIEF DESCRIPTION OF THE ACCOMPANYING DRAWINGS

FIG. 1 is a flowchart of a method for calculating a transient overvoltage at a DC sending end by taking into account a dynamic process of a control system according to Embodiment one of the present disclosure;

FIG. 2 is a flowchart of a method for calculating a transient overvoltage at a DC sending end by taking into account a dynamic process of a control system according to Embodiment two of the present disclosure;

FIG. 3 is a schematic diagram of a constant current control apparatus in the method for calculating a transient overvoltage at a DC sending end by taking into account a dynamic process of a control system according to Embodiment two of the present disclosure;

FIG. 4 is a schematic diagram of a DC line adjusting apparatus in the method for calculating a transient overvoltage at a DC sending end by taking into account a dynamic process of a control system according to Embodiment two of the present disclosure;

FIG. 5 is a schematic diagram of an equivalent circuit of a DC line in the method for calculating a transient overvoltage at a DC sending end by taking into account a dynamic process of a control system according to Embodiment two of the present disclosure;

FIG. 6 is a schematic diagram of another equivalent circuit of the DC line in the method for calculating a transient overvoltage at a DC sending end by taking into account a dynamic process of a control system according to Embodiment two of the present disclosure;

FIG. 7 is a schematic diagram of an equivalent circuit of a DC power transmission system in the method for calculating a transient overvoltage at a DC sending end by taking into account a dynamic process of a control system according to Embodiment two of the present disclosure;

FIG. 8 is a block diagram of an apparatus for calculating a transient overvoltage at a DC sending end by taking into account a dynamic process of a control system according to Embodiment three of the present disclosure; and

FIG. 9 is a schematic diagram of a device according to Embodiment four of the present disclosure.

### DETAILED DESCRIPTION OF ILLUSTRATIVE EMBODIMENTS

Hereinafter the present disclosure will be described in further detail in connection with the drawings and embodiments. It is to be understood that the specific embodiments set forth below are intended to illustrate and not to limit the present disclosure. Additionally, it is to be noted that for convenience of description, only part rather than all of the arrangement related to the present disclosure are illustrated in the drawings. In addition, the embodiments and features recited in these embodiments of the present disclosure may be randomly combined with each other, if no contradiction is present.

### Embodiment One

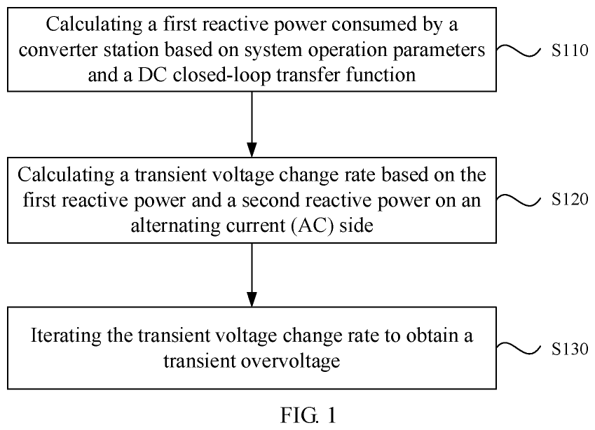

FIG. 1 is a flowchart of a method for calculating a transient overvoltage at a DC sending end by taking into account a dynamic process of a control system according to Embodiment one of the present disclosure. This embodiment is applicable to purposes for determining a transient overvoltage of a sending-end power grid after a three-phase short circuit fault occurs in a receiving-end power grid of a DC electric power transmission system. The method may be executed by an apparatus for calculating a transient overvoltage at a DC sending end by taking into account a dynamic process of a control system, and the apparatus may be implemented in the form of software and/or hardware.

First, it should be noted that the method for calculating the transient overvoltage provided in this embodiment may be applied to a terminal, such as a computer device, to analyze the operation parameters and the device parameters at the sending end during the transient process, so as to determine the transient overvoltage and provide theoretical data support for fault repair and subsequent grid construction. The receiving-end power grid refers to an electric power system in which loads are coupled to these power assignments by using a relatively dense electric power network, centering around a load-concentrated area including within the area and adjacent power plants, while the receiving-end power grid receives active electric power and electric energy delivered from external and remote power sources to achieve a supply-demand balance. The sending-end power grid refers to an electric power system in which the total active capacity of power generation is greater than the total load capacity in the power plant-concentrated area so that it has the ability to output active power to other power grids. In this embodiment, the excess active capacity of the sending-end power grid is transmitted to the receiving-end power grid through a DC line.

Further, the three-phase AC of the sending-end power grid is rectified to a DC by a sending-end converter station, and then the DC is sent to the receiving-end power grid through a DC electric power transmission line, and the receiving-end converter station of the receiving-end power grid inverts the DC into a three-phase AC to power the load. It should be noted that in a DC electric power transmission system, a rectifier is generally used in a sending-end converter station to rectify a three-phase AC into a DC, and an inverter is generally used in a receiving-end converter station to invert a DC into a three-phase AC.

As illustrated in FIG. 1, the method for calculating a transient overvoltage at a DC sending end by taking into account a dynamic process of a control system according to an embodiment of the present disclosure mainly includes the following steps.

In S110, a first reactive power consumed by a converter station is calculated based on system operation parameters and a DC closed-loop transfer function.

It should be noted that the converter station described in this embodiment all refers to the converter station on the sending-end power grid side. The system operation parameters mainly include the operation parameters of the electric power transmission system in normal operation, the system parameters when a three-phase short circuit fault occurs in the receiving-end power grid, and the device parameters of the electric power transmission system. In this embodiment, the system operation parameters mainly include: a constant current control total gain K, a resistor R of the DC line, an inductance L of the DC line, a per unit quantity X_{T}* of the leakage reactance, a short-circuit capacity S_{d}, a reactive power compensation capacity Q_{c} of the AC power grid, an arranged DC power Pₐ, a given DC voltage U_{z} on a rectifier side, an AC voltage U₂ on a secondary side of the transformer, an AC rated voltage U_{2N} on the secondary side of the transformer, a rated capacity S_{N} of the DC line, a per unit quantity U₀* of the commutation bus voltage during normal operation, and the like.

The DC closed-loop transfer function may be understood as a system transfer function that takes into account the DC circuit and the rectifier in the sending-end converter station, that is, a transfer function of an entire DC closed-loop system including the rectifier and the DC line to the rectifier voltage disturbance. In this embodiment, the open-loop transfer function of the DC circuit and the closed-loop transfer function of the rectifier may be separately determined according to the control mode of the DC electric power transmission system. The DC closed-loop transfer function is obtained by transforming the open-loop transfer function of the DC line and the open-loop transfer function of the rectifier.

Further, a rectifier in the sending-end converter station generally adopts a constant current control mode. The constant current control apparatus is generally formed by an adjusting amplifier, a non-linear link, a phase control and trigger circuit, a converter, and a DC current transformer. The open-loop transfer function of the rectifier in the constant current control mode is obtained by multiplying the transfer function of each link.

Further, the rectifier in the sending-end converter station generally adopts the constant current control mode, and the inverter in the receiving-end converter station generally adopts a constant extinction angle control mode. An equivalent circuit of the entire DC electric power transmission system including the rectifier and the DC line is obtained according to the adjustment characteristics of the DC electric power transmission system when the rectifier adopts constant current adjustment while the inverter adopts constant extinction angle adjustment. Thus, a DC open-loop transfer function is obtained. According to the change of the rectifier voltage, the current variable at the beginning of the DC line is obtained, and thus the DC closed-loop transfer function is obtained.

In the embodiment, the first reactive power may be understood as the reactive power consumed by the converter station on the DC power grid side. Further, the DC current of the DC line is determined through the DC closed-loop transfer function, and the DC voltage on the rectifier side before the fault occurs and the DC voltage on the rectifier side when the fault occurs are obtained from the AC voltage on the secondary side of the transformer according to the relationship between the constant current control mode and trigger angle on the rectifier side; and the first reactive power consumed by the converter station is obtained through the DC current and the DC voltage.

In S120, a transient voltage change rate is calculated according to the first reactive power and a second reactive power on an AC side.

In this embodiment, the second reactive power on the AC side may be understood as the reactive power emitted by the filter on the AC side. It should be noted that the AC side in the embodiment may be understood as a system before the rectifier in the sending-end converter station. The transient voltage change rate may be understood as the change rate at the sending-end commutation bus during the transient process.

Further, the amount of change in the reactive exchange between the converter station and the AC side is determined according to the first reactive power consumed by the converter station and the second reactive power on the AC side, and a reactive surplus of the sending-end converter station is obtained. The transient voltage change rate is obtained according to the relationship between the voltage rise amplitude, the reactive surplus, and the system short-circuit capacity.

In S130, the transient voltage change rate is iterated to obtain a transient overvoltage.

In the embodiment, since the second reactive power emitted by the filter on the AC side is proportional to the voltage of the commutation bus in S120, it cannot be predicted. The second reactive power emitted by the filter is approximated to a fixed value, which is smaller than the actual reactive power emitted by the filter when the overvoltage occurs at the commutation bus, and therefore the transient overvoltage change rate obtained in S120 is relatively small. So it is needed to perform the iterative calculation on the transient voltage change rate for multiple times so that the curve of the second reactive power emitted by the filter gradually approaches the actual value of the second reactive power emitted by the filter.

The value of the transient voltage change rate is generally a value given according to the actual situation. The voltage at the commutation bus is recalculated according to the transient voltage change rate and the current voltage at the commutation bus. That is, the recalculated voltage at the commutation bus is equal to the sum of the transient voltage change rate and the current voltage at the commutation bus. According to the recalculated voltage at the commutation bus and the susceptance of the filter, a new transient voltage change rate is obtained. Then, the voltage at the commutation bus is recalculated again. The obtained transient voltage change rate is not used as the transient overvoltage until the obtained transient voltage change rate makes the curve of the second reactive power emitted by the filter infinitely close to the actual value of the reactive power emitted by the filter.

In the method for calculating a transient overvoltage at a DC sending end by taking into account a dynamic process of a control system, first the first reactive power consumed by a converter station is calculated based on system operation parameters and a DC closed-loop transfer function Then the transient voltage change rate is calculated according to the first reactive power and a second reactive power on an AC side. Finally the transient voltage change rate is iterated to obtain the transient overvoltage. According to the technical solution provided by this embodiment of the present disclosure, the transient overvoltage is determined according to the system operation parameters and the closed-loop transfer function of a DC line, the dynamic process of a control parameter change caused by a control action of the control system after a fault occurs can be determined by the closed-loop transfer function of the DC line, whereby the transient overvoltage can be determined. The embodiment takes into account the dynamic process of the DC control system, and can reflect the actual operation of the DC electric power transmission system, leading to a more accurate calculation result.

### Embodiment Two

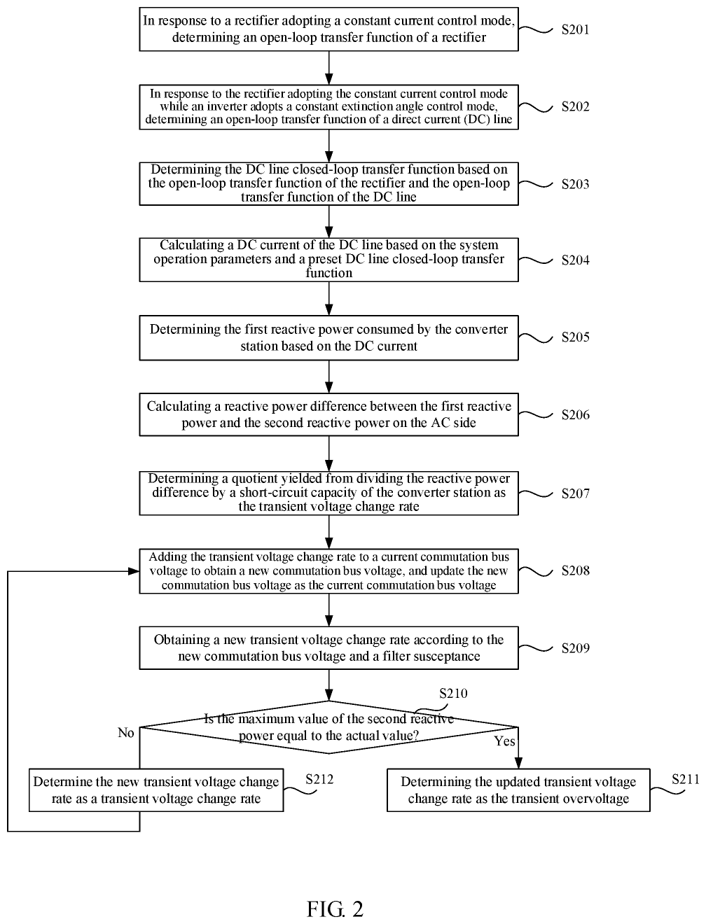

Based on the above embodiment, this embodiment according to the present disclosure further optimizes the method for calculating a transient overvoltage at a DC sending end that takes into account a dynamic process of a control system. FIG. 2 is a flowchart of the method for calculating a transient overvoltage at a DC sending end by taking into account a dynamic process of a control system according to Embodiment two of the present disclosure. As illustrated in FIG. 2, the optimized method for calculating a transient overvoltage at a DC sending end by taking into account a dynamic process of a control system mainly includes the following steps.

In S210, when a rectifier adopts a constant current control mode, an open-loop transfer function of the rectifier is determined.

In this embodiment, the rectifier refers to a rectifier in a sending-end converter station. The open-loop transfer function of the rectifier may be understood as an open-loop transfer function of the entire rectifier system including the rectifier circuit and the rectifier control circuit.

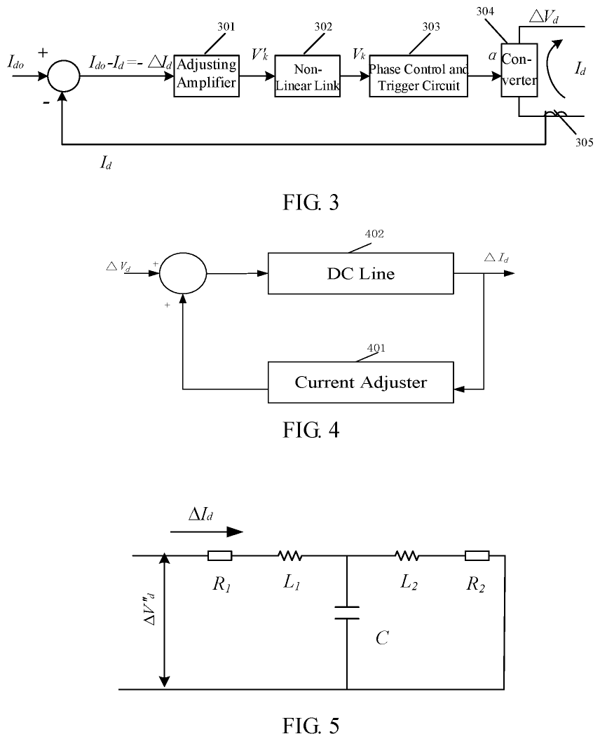

Further, a rectifier in the sending-end converter station generally adopts a constant current control mode. FIG. 3 is a schematic diagram of a constant current control apparatus in the method for calculating a transient overvoltage according to Embodiment two of the present disclosure. As illustrated in FIG. 3, the constant current control apparatus is generally formed by an adjusting amplifier 301, a non-linear link 302, a phase control and trigger circuit 303, a converter 304, and a DC current transformer 305. The open-loop transfer function of the rectifier in the constant current control mode is obtained by multiplying the transfer function of each link.

The basic principle of the constant current control mode is to compare the actual DC current I_{d} measured by the DC current transformer 305 with the DC setting current I_{do}, and then amplify the error ε=I_{do}−I_{d} through the adjusting amplifier 301. The output of the adjusting amplifier 301 is used for controlling the phase control and trigger circuit 303 to change the trigger angle to reduce the current error value. It should be noted that in the embodiment, the constant current control mode is set to operate under a linear condition without considering the non-linear link, and the converter 304 is preferably a rectifier.

For the rectifier, if the measured actual DC current I_{d} is less than the DC setting current I_{do}, the trigger angle α must be reduced to increase the output voltage V_{do} cos α of the rectifier to increase the actual DC current I_{d}. V_{do} is the average of the DC voltages in the DC line. If the actual DC current I_{d} is greater than the DC setting current I_{do}, the trigger angle α must be increased to reduce the output voltage V_{do} cos α of the rectifier to reduce the actual DC current I_{d}.

In this embodiment, the constant current control mode is set to be analog, that is, the input quantities and the output quantities of the adjustment amplifier 301 and the nonlinear link 302 are all analog quantities.

First, when the adjusting amplifier 301 performs adjustment according to a deviation ratio, the transfer function G_{T}(P) of the adjusting amplifier 301 is as follows:

$${G}_{T} ( p ) = \frac{Δ {V}_{K}^{′}}{ɛ} = - \frac{{K}_{T}}{1 + p {T}_{T}} . \qquad ( 1 )$$

ΔV′_{K} is the voltage deviation of the adjusting amplifier, K_{T} is the gain of the adjusting amplifier, T_{T} is the time constant of the adjusting amplifier, and p is an operator of the Laplace transform.

It should be noted that the topology of the existing DC electric power transmission system determines that the adjusting amplifier 301 is to perform adjustment according to the deviation ratio.

Further, the adjustment characteristic of the phase control and trigger circuit 303 is as follows:

α=K_{α}V_{K} (2).

V_{K} is the voltage of the phase control and trigger circuit, and K_{α} is the gain of the phase control circuit.

Further, the transfer function of the phase control and trigger circuit 303 is as follows:

$${G}_{α} ( p ) = \frac{Δ α}{Δ {V}_{K}} = {K}_{α} . \qquad ( 3 )$$

ΔV_{K} is the amount of change in the voltage of the phase control and trigger circuit, and Δα is the amount of change in the trigger angle.

Further, it is assumed that the output of the converter 304 is represented by a voltage V_{d}=V_{do} cos α, and the transfer function of the converter 304 is as follows:

$${G}_{h} ( p ) = \frac{Δ {V}_{d}}{Δ α} = \frac{{V}_{d 0} [ cos ( α + Δ α ) - cos α ]}{Δ α} \approx - {V}_{d 0} sin α . \qquad ( 4 )$$

In the case of not considering the non-linear link 302, the output voltage V′_{K} of the adjusting amplifier 301 is equal to the input voltage V_{K} of the phase control and trigger circuit 303. The above formulas (1), (3) and (4) are multiplied to obtain the open-loop transfer function, as described below, in the constant current control mode:

$${G}_{I} ( p ) = \frac{Δ {V}_{d}}{ɛ} = \frac{{K}_{T} {K}_{α}}{1 + {T}_{T} p} ( {V}_{do} sin α ) = \frac{K}{1 + {T}_{T} p} . \qquad ( 5 )$$

K=K_{T}K_{α}V_{do} sin α is the open-loop gain of the rectifier in the constant current control mode.

As can be seen, since the converter 304 has a non-linear control characteristic, the adjustment gain is not a constant and varies with the operation state of the converter 304. For example, the trigger angle of the rectifier may vary in the range of α=5°˜90°, and K may vary by

$$\frac{sin 90 °}{sin 5 °} \approx 11.5$$

times. Therefore, it is difficult to achieve satisfactory adjustment quality at all α angles without taking certain measures.

In order to overcome the above disadvantages, the non-linear link 302 is introduced into the constant current control mode, and an adjustment characteristic of the non-linear link 302 is as follows:

$${V}_{K} = {K}_{b 2} {cos}^{- 1} ( - \frac{{V}_{K}^{′}}{{K}_{b 1}} ) . \qquad ( 6 )$$

K_{b1} and K_{b2} are transform coefficients. A is substituted into a formula (6) to obtain a formula as follows:

$${V}_{K}^{′} = - {K}_{b 1} cos ( \frac{α}{{K}_{α} {K}_{b 2}} ) . \qquad ( 7 )$$

K_{α}K_{b2}=1, and

V′_{K}=−K_{b1} cos(α) (8).

Thus, the output voltage of the converter 304 is as follows:

$${V}_{d} = {V}_{do} cos α = - {V}_{do} \frac{{V}_{K}^{′}}{{K}_{b 1}} . \qquad ( 9 )$$

The transfer function including the non-linear link 302, the phase control circuit 303 and the converter 304 is as follows:

$${G}_{α h} ( p ) = \frac{Δ {V}_{d}}{Δ {V}_{K}^{′}} = - \frac{{V}_{d 0}}{{K}_{b 1}} . \qquad ( 10 )$$

The formula (1) and the formula (10) are multiplied to obtain an open-loop transfer function, as described below, of the rectifier including the non-linear link:

$${G}_{I} ( p ) = \frac{Δ {V}_{d}}{ɛ} = \frac{{K}_{T} \frac{{V}_{do}}{{K}_{b 1}}}{1 + p {T}_{T}} = \frac{K}{1 + p {T}_{T}} . \qquad ( 11 )$$

The open-loop adjustment gain

$$K = \frac{{K}_{T} {V}_{d o}}{{K}_{b 1}}$$

is a constant.

In S202, when the rectifier adopts the constant current control mode and an inverter adopts a constant extinction angle control mode, an open-loop transfer function of the DC line is determined.

In this embodiment, the DC line refers to a high-voltage DC electric power transmission line between two converter stations. FIG. 4 is a schematic diagram of a DC line adjusting apparatus in the method for calculating a transient overvoltage at a DC sending end by taking into account a dynamic process of a control system according to Embodiment two of the present disclosure. As illustrated in FIG. 4, the DC line adjusting apparatus is mainly formed by a current adjuster 401 and a DC line 402.

From FIG. 4, it can be seen that the amount ΔV_{d} of disturbance of the rectifier voltage is as follows:

$$Δ {V}_{d} = {G}_{I} ( p ) Δ {I}_{d} + \frac{Δ {I}_{d}}{{G}_{d} ( p )} . \qquad ( 12 )$$

G_{I}(p) is a transfer function of the current adjuster 401 and G_{d}(p) is a transfer function of the DC line 402.

Thus, as can be seen from FIG. 4, the transfer function of the closed-loop system of the DC line adjusting apparatus to the amount ΔV_{d} of disturbance is as follows:

$$\frac{Δ {I}_{d}}{Δ {V}_{d}} = \frac{1}{{G}_{I} ( p ) + \frac{1}{{G}_{d} ( p )}} \qquad ( 13 )$$

FIG. 5 is a schematic diagram of an equivalent circuit of a DC line in the method for calculating a transient overvoltage at a DC sending end by taking into account a dynamic process of a control system according to Embodiment two of the present disclosure. As can be seen in FIG. 5, when the amount of change in the unloaded voltage of the converter is ΔV″_{d}, the variable ΔI_{d} of the current at the beginning of the DC line can be obtained as follows:

$$\begin{matrix}Δ {I}_{d} = \frac{Δ {V}_{d}^{″}}{{R}_{1} + {pL}_{1} + \frac{\frac{( {R}_{2} + {pL}_{2} )}{pC}}{{R}_{2} + {pL}_{2} + \frac{1}{pC}}} = \frac{Δ {V}_{d}^{″}}{Z ( p )} . & ( 14 ) \\ {Z}_{( p )} = {R}_{1} + {pL}_{1} + \frac{\frac{( {R}_{2} + {pL}_{2} )}{pC}}{{R}_{2} + {pL}_{2} + \frac{1}{pC}} . & ( 15 )\end{matrix}$$

From a formula (15), the open-loop transfer function of the DC line can be obtained as follows:

$${G}_{d} ( p ) = \frac{Δ {I}_{d}}{Δ {V}_{d}^{″}} = \frac{1}{Z ( p )} . \qquad ( 16 )$$

In S203, the DC closed-loop transfer function is determined according to the open-loop transfer function of the rectifier and the open-loop transfer function of the DC line.

The DC closed-loop transfer function can be obtained, as described below, by substituting a formula (16) into a formula (13):

$$\frac{Δ {I}_{d}}{Δ {V}_{d}} = \frac{{I}_{do} - {I}_{d}}{{V}_{do} - {V}_{d}} = \frac{I}{K + Z ( p )} . \qquad ( 17 )$$

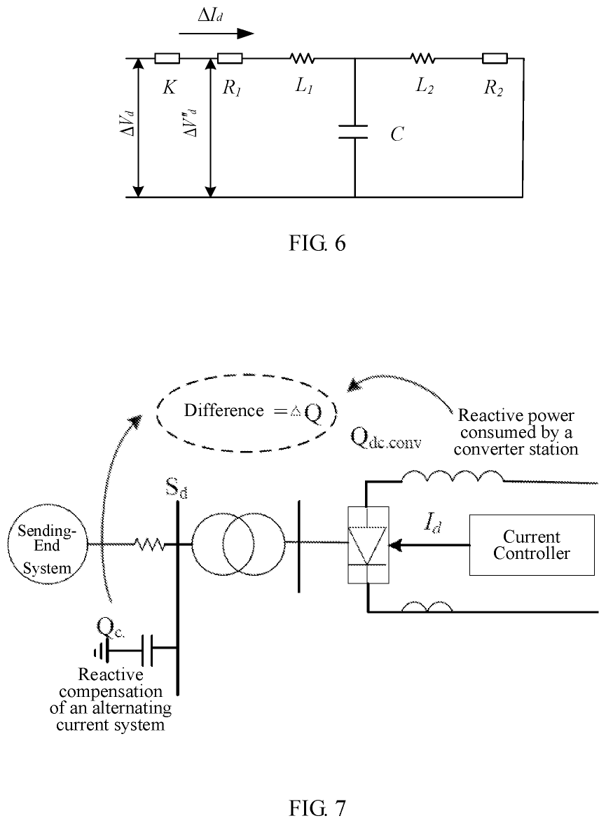

I_{d} is the DC current of the DC line, and I_{do} is the DC setting current. FIG. 6 is a schematic diagram of another equivalent circuit of the DC line in the method for calculating a transient overvoltage at a DC sending end by taking into account a dynamic process of a control system according to Embodiment two of the present disclosure. A formula (17) may be represented by the equivalent circuit of FIG. 6.

In S204, the DC current of the DC line is calculated according to the system operation parameters and a preset DC closed-loop transfer function.

In the embodiment, the system operation parameters mainly include: a constant current control total gain K, a resistor R of the DC line, an inductance L of the DC line, a per unit quantity X_{T}* of the leakage reactance, a short-circuit capacity S_{d}, a reactive power compensation capacity Q_{c} of the AC power grid, an arranged DC power Pₐ, a given DC voltage U_{z} on a rectifier side, an AC voltage U₂ on a secondary side of the transformer, an AC rated voltage U_{2N} on the secondary side of the transformer, a rated capacity S_{N} of the DC line, a per unit quantity U₀* of the commutation bus voltage during normal operation, and the like.

S204 includes two steps S2041 and S2042.

In S2041, an association relationship between a DC current, a DC setting current, a DC normal voltage, and a DC fault voltage is determined according to the closed-loop transfer function of the DC line.

In the embodiment, the DC closed-loop transfer function, i.e., the formula (17), based on the constant current control mode is obtained through explanation of the basic adjustment principle of the constant current and derivation of the formula. The DC current I_{d} is derived from the following formula (12):

$${I}_{d} = {I}_{do} - \frac{1}{K + Z ( P )} ( {V}_{do} - {V}_{d} ) . \qquad ( 18 )$$

In S2042, the DC current of the DC line is calculated according to the DC setting current, the DC normal voltage, the DC fault voltage and the association relationship.

The DC normal voltage refers to the DC voltage on the rectifier side at the normal operation time. The DC fault voltage refers to the DC voltage on the rectifier side when the fault occurs.

The DC setting current I_{d0} may be obtained from the following formula:

$${I}_{do} = \frac{{P}_{a}}{{U}_{z}} . \qquad ( 19 )$$

Pₐ is arranged DC power, and U_{z} is a given DC voltage on the rectifier side. The arranged DC power Pa may be understood as the active power planned to be transmitted by the DC electric power transmission system.

Further, in solving the DC current I_{d}, an inverse Laplace transform needs to be performed to transform a frequency domain function F(s) to a time domain function ƒ(t). Since the pole control system is delayed by 200 ms, all AC filters of the converter station are cut off, and t is taken as 0.2 s. The constant current acts to shift the trigger angle on the rectifier side from 15° at normal operation to about 130°, and thereby the DC normal voltage V_{d0} and the DC normal voltage V_{d} can be obtained according to the following formulas:

$$\begin{matrix}{V}_{do} = \frac{3 \sqrt{6}}{π} {U}_{2} cos {15}^{∘} & ( 20 ) \\ {V}_{d} = \frac{3 \sqrt{6}}{π} {U}_{2} cos {130}^{∘} . & ( 21 )\end{matrix}$$

U₂ is the AC voltage on the secondary side of the transformer. As the trigger angle α increases, the DC current I_{d} gradually decreases. At this time, the DC current is substantially reduced to a minimum value after a delay.

In S205, the first reactive power consumed by the converter station is determined based on the DC current.

In the embodiment, the converter station refers to a converter station in sending-end power grid. The first reactive power Q_{dc.conv} refers to the reactive power consumed by the converter station in the sending-end power grid.

S205 includes three steps S2051, S2052 and S2053.

In S2051, a commutation angle of the rectifier is calculated according to device parameters of a transformer.

In this embodiment, the device parameters of the transformer mainly include: X_{T}*_{(N)}, which is a per unit quantity of the leakage reactance, U_{2N}, which is the voltage on the secondary side of the transformer, and S_{N}, which is the rated capacity of the transformer. The leakage reactance X_{T} of the transformer is calculated according to the device parameters of the transformer, where a formula of the leakage reactance of the transformer is as follows:

$${X}_{T} = {X}_{T• ( N )} \frac{{U}_{N}^{2}}{{S}_{N}} . \qquad ( 22 )$$

The commutation angle of the rectifier is calculated according to the leakage reactance X_{T} of the transformer, the DC voltage I_{d}, and the first AC voltage U₂ on the secondary side of the transformer. The calculation formula of the commutation angle of the rectifier is as follows:

$$μ = arccos ( cos α - \frac{2}{\sqrt{ó}} \frac{{X}_{T} {I}_{d}}{{U}_{2}} ) - α . \qquad ( 23 )$$

In S2052, an ideal unloaded first DC voltage of the DC line is determined according to a first AC voltage on a secondary side of the transformer.

Through the first AC voltage U₂ on the secondary side of the transformer, the ideal unloaded DC voltage is obtained as U_{dio}:

$${U}_{dio} = \frac{3 \sqrt{6}}{π} {U}_{2} . \qquad ( 24 )$$

In S2053, the first reactive power consumed by the converter station is obtained according to the first DC voltage, the DC current of the DC line, the commutation angle of the rectifier and a preset calculation formula.

The calculation formula of the first reactive power Q_{dc.conv} consumed by the converter station is as follows:

$${Q}_{dc . conv} = \frac{1}{2} \frac{2 μ + sin 2 α - sin 2 ( α + μ )}{cos α - cos ( α + μ )} {I}_{d} {U}_{dio} . \qquad ( 25 )$$

α is the trigger angle; μ is the commutation angle; I_{d} is the DC current; and U_{dio} is the ideal unloaded DC voltage. α may be considered as 130° under constant current control.

In S206, a reactive power difference between the first reactive power and the second reactive power on the AC side is calculated.

FIG. 7 is a schematic diagram of an equivalent circuit of a DC electric power system in the method for calculating a transient overvoltage at a DC sending end by taking into account a dynamic process of a control system according to Embodiment two of the present disclosure. As illustrated in FIG. 7, the reactive power difference, as described below, between the first reactive power and the second reactive power on the AC side is a reactive surplus of the sending-end converter station:

ΔQ=Q_{c}−Q_{dc.conv} (26).

Q_{c} is the second reactive power emitted by the filter on the AC side, Q_{dc.conv} is the first reactive power consumed by the converter station, and ΔQ is the difference between the reactive power consumed by the converter station on the DC side.

In S207, a quotient yielded from dividing the reactive power difference by a short-circuit capacity of the converter station is determined as the transient voltage change rate.

The transient voltage change rate is calculated according to the relationship among the voltage rise amplitude, the reactive surplus and the system short-circuit capacity. It should be noted that the voltage rise amplitude may be understood as the voltage change rate.

According to the relationship among the voltage rise amplitude, the reactive surplus and the system short-circuit capacity, the following formula is obtained:

$$ΔU = \frac{Δ Q}{{S}_{d}} . \qquad ( 27 )$$

In S208, the transient voltage change rate is added to a current commutation bus voltage to obtain a new commutation bus voltage, and the new commutation bus voltage is updated as the current commutation bus voltage.

In the embodiment, since the second reactive power emitted by the filter on the AC side is proportional to the voltage of the commutation bus, it cannot be predicted. The second reactive power emitted by the filter is approximated to a fixed value. The fixed value is smaller than the actual reactive power emitted by the filter when the overvoltage occurs at the commutation bus. Therefore, the transient overvoltage change rate obtained from the formula (27) is relatively smaller. So it is necessary to perform the iterative calculation on the transient voltage change rate for multiple times so that the curve of the second reactive power emitted by the filter gradually approaches the actual value of the second reactive power emitted by the filter.

The value of the initial transient voltage change rate is first determined, and is generally a value given according to the actual situation. Further, the value of the initial transient voltage change rate is obtained according to the formula (27). Then, the new commutation bus voltage is equal to the sum of the transient voltage change rate and the current commutation bus voltage. The new commutation bus voltage is updated as the current commutation bus voltage for iterative calculation.

In S209, a new transient voltage change rate is obtained according to the new commutation bus voltage and a filter susceptance.

In this embodiment, the second reactive power emitted by the filter on the AC side is calculated according to the new commutation bus voltage and the filter susceptance. The formula of the second reactive power is as follows:

Q_{c}=U⁷B (28).

U is the recalculated voltage at the commutation bus and B is the susceptance of the filter.

In S210, it is determined whether the maximum value of the second reactive power is equal to the actual value. If the maximum value of the second reactive power is not equal to the actual value, turn to perform S212. If the maximum value of the second reactive power is equal to the actual value, turn to perform S211.

In S211, the updated transient voltage change rate is determined as a transient overvoltage.

In S212, the new transient voltage change rate is updated to the transient voltage change rate, and S208 is returned to and performed.

In the embodiment, it is determined whether the maximum value of the second reactive power is equal to the actual value. If the maximum value of the second reactive power is smaller than the actual value, the new transient voltage change rate is updated to the transient voltage change rate. The process returns to a step in which the transient voltage change rate is added to the current commutation bus voltage to obtain a new commutation bus voltage, and the new commutation bus voltage is updated as the current commutation bus voltage. The new transient voltage change rate is not updated to the transient voltage change rate until the maximum value of the second reactive power gradually approaches the actual value.

According to the technical solution provided in the embodiment, the adjustment characteristics of the DC system when the rectifier adopts the constant current adjustment and the inverter adopts the constant extinction angle adjustment are analyzed, the DC closed-loop transfer function is derived, the amount of change in the reactive exchange between the converter station and the AC system is analyzed, and the transient voltage change rate is obtained and is iterated repeatedly to obtain the transient overvoltage at the DC sending end, which satisfy a variety of requirements in practical applications.

This embodiment establishes an effective mapping between the DC sending-end transient overvoltage and the DC control link by analyzing the dynamic characteristics of the sending-end system DC element under the AC/DC fault disturbance and the change of the transient reactive characteristic of the DC sending-end after the fault, and provides theoretical support for a method for quickly estimating the transient overvoltage at the DC sending end by taking into account the dynamic behavior of the DC element control system.

### Embodiment Three

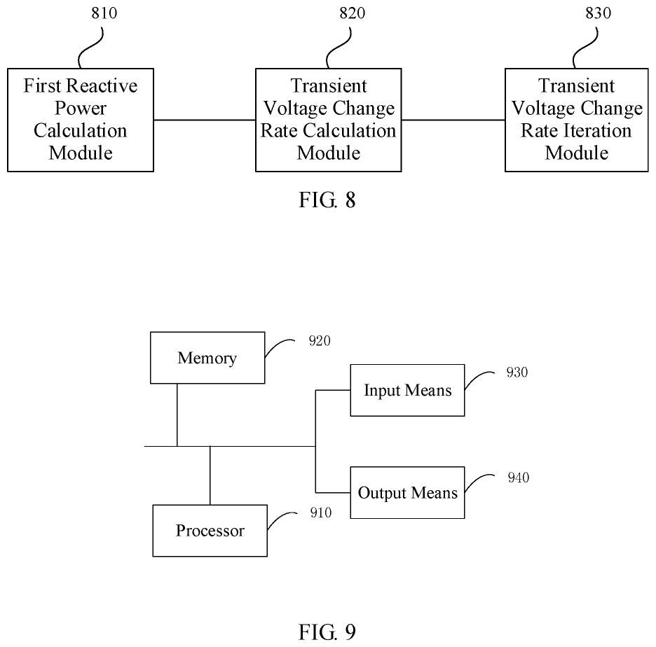

FIG. 8 is a block diagram of an apparatus for calculating a transient overvoltage at a DC sending end by taking into account a dynamic process of a control system according to Embodiment three of the present disclosure. The embodiment is applicable to purposes for determining the transient overvoltage at the DC sending end of sending-end power grid by taking into account a dynamic process of a control system after a three-phase short circuit fault occurs in receiving-end power grid of a DC electric power transmission system. The apparatus may be implemented in the form of software and/or hardware.

As illustrated in FIG. 8, the apparatus for calculating a transient overvoltage at a DC sending end by taking into account a dynamic process of a control system according to this embodiment of the present disclosure mainly includes a first reactive power calculation module 810, a transient voltage change rate calculation module 820, and a transient voltage change rate iteration module 830.

The first reactive power calculation module 810 is configured to calculate a first reactive power consumed by a converter station based on system operation parameters and a DC closed-loop transfer function.

The transient voltage change rate calculation module 820 is configured to calculate a transient voltage change rate based on the first reactive power and a second reactive power on an AC side.

The transient voltage change rate iteration module 830 is configured to iterate the transient voltage change rate to obtain a transient overvoltage.

For the apparatus for calculating a transient overvoltage at a DC sending end by taking into account a dynamic process of a control system, first the first reactive power consumed by a converter station is calculated based on system operation parameters and a DC closed-loop transfer function. Then the transient voltage change rate is calculated according to the first reactive power and a second reactive power on an AC side. Finally the transient voltage change rate is iterated to obtain the transient overvoltage at the DC sending end by taking into account the dynamic process of the control system. According to the technical solution provided by the embodiment of the present disclosure, the transient overvoltage at the DC sending end by taking into account the dynamic process of the control system is determined based on the system operation parameters and the closed-loop transfer function of the DC line, the dynamic process of a control parameter change caused by a control action of the control system after a fault occurs in the system can be determined by the closed-loop transfer function of the DC line, whereby the transient overvoltage at the DC sending end can be determined by taking into account the dynamic process of the control system. This embodiment takes into account the dynamic process of the DC control system, and so can reflect the actual operation of the system, resulting in a more accurate calculation result.

Further, the first reactive power calculation module 810 includes a DC current calculation unit and a first reactive power calculation unit.

The DC current calculation unit is configured to calculate a DC current of a DC line based on the system operation parameters and a preset DC closed-loop transfer function.

The first reactive power calculation unit is configured to determine the first reactive power consumed by the converter station based on the DC current.

Specifically, the DC current calculation unit is configured to determine an association relationship between a DC current, a DC setting current, a DC normal voltage, and a DC fault voltage according to the DC closed-loop transfer function, and calculate the DC current of the DC line based on the DC setting current, the DC normal voltage, the DC fault voltage, and the association relationship.

Specifically, the first reactive power calculation unit is configured to calculate a commutation angle of the rectifier according to device parameters of a transformer, determine an ideal unloaded first DC voltage of the DC line based on a first AC voltage on a secondary side of the transformer, and obtain the first reactive power consumed by the converter station based on the first DC voltage, the DC current of the DC line, the commutation angle of the rectifier, and a preset calculation formula.

Further, the apparatus further includes a rectifier open-loop transfer function determination module, a DC line open-loop transfer function determination module, and a DC closed-loop transfer function module.

The rectifier open-loop transfer function determination module is configured to, in response to a rectifier adopting a constant current control mode, determine an open-loop transfer function of the rectifier.

The DC line open-loop transfer function determination module is configured to, in response to the rectifier adopting the constant current control mode and an inverter adopting a constant extinction angle control mode, determine an open-loop transfer function of the DC line.

The DC closed-loop transfer function module is configured to determine the DC closed-loop transfer function based on the open-loop transfer function of the rectifier and the open-loop transfer function of the DC line.

Further, the transient voltage change rate calculation module 820 includes a reactive power difference calculation unit and a transient voltage change rate determination unit.

The reactive power difference calculation unit is configured to calculate a reactive power difference between the first reactive power and the second reactive power on the AC side.

The transient voltage change rate determination unit is configured to determine a quotient yielded from dividing the reactive power difference by short-circuit capacity of the converter station as the transient voltage change rate.

Further, the transient voltage change rate iteration module 830 includes a commutation bus voltage calculation unit, a new transient voltage change rate calculation unit, and a transient overvoltage iteration unit.

The commutation bus voltage calculation unit is configured to add the transient voltage change rate to a current commutation bus voltage to obtain a new commutation bus voltage, and update the new commutation bus voltage as the current commutation bus voltage.

The new transient voltage change rate calculation unit is configured to obtain a new transient voltage change rate based on the new commutation bus voltage and filter susceptance.

The transient overvoltage iteration unit is configured to update the new transient voltage change rate to the transient voltage change rate, return to perform the operation of determining a new commutation bus voltage until the maximum value of the second reactive power is equal to an actual value, and determine an updated transient voltage change rate as the transient overvoltage.

The apparatus for calculating a transient overvoltage at a DC sending end by taking into account a dynamic process of a control system provided in the embodiment can execute the method for calculating a transient overvoltage at a DC sending end by taking into account a dynamic process of a control system provided in any embodiment of the present disclosure, and has functional modules and beneficial effects corresponding to the execution method.

### Embodiment Four

FIG. 9 is a schematic diagram of a device according to Embodiment four of the present disclosure. As illustrated in FIG. 9, the device includes a processor 910, a memory 920, an input means 930, and an output means 940. The number of processors in the device may be one or more and one processor 910 is taken as an example in FIG. 9. The processor 910, the memory 920, the input means 930 and the output means 940 in the device may be connected through a bus or in other ways. In FIG. 9, the connection through a bus is taken as an example.

The memory 920, as a computer-readable storage medium, may be configured to store software programs, computer-executable programs and modules, such as program instructions/modules (e.g., the first reactive power calculation module 810, the transient voltage change rate calculation module 820 and the transient voltage change rate iteration module 830 in the apparatus for calculating a transient overvoltage at a DC sending end by taking into account a dynamic process of a control system) corresponding to the method for calculating a transient overvoltage at a DC sending end by taking into account a dynamic process of a control system. The processor 910 executes the software programs, instructions and modules stored in the memory 920 so as to perform various function applications and data processing, that is, to implement the above method for calculating a transient overvoltage at a DC sending end by taking into account a dynamic process of a control system.

The memory 920 may mainly include a program storage area and a data storage area. The program storage area may store an operating system and an application program required by at least one function. The data storage area may store data and the like created according to the use of the terminal. Furthermore, the memory 920 may include a high-speed random access memory, and may also include a nonvolatile memory such as at least one disk memory, a flash memory or another nonvolatile solid-state memory. In some examples, the memory 920 may further include memories that are remotely disposed with respect to the processors 910. These remote memories may be connected to the device via a network. Examples of the preceding network include, but are not limited to, the Internet, an intranet, a local area network, a mobile communication network and a combination thereof.

The input means 930 may be used for receiving input digital or character information and for generating key signal input related to user settings and function control of the device. The output means 940 may include display devices such as a display screen.

### Embodiment Five

The embodiment five of the present disclosure further provides a storage medium containing computer-executable instructions that, when executed by a computer processor, perform a method for calculating a transient overvoltage at a DC sending end by taking into account a dynamic process of a control system. The method includes the following steps.

First a reactive power consumed by a converter station is calculated based on system operation parameters and a DC closed-loop transfer function.

A transient voltage change rate is calculated based on the first reactive power and a second reactive power on an AC side.

The transient voltage change rate is iterated to obtain a transient overvoltage.

Of course, in the storage medium containing computer-executable instructions provided by the embodiments of the present disclosure, the computer-executable instructions implement not only the above method operations but also related operations in the method for calculating a transient overvoltage at a DC sending end by taking into account a dynamic process of a control system provided by any embodiment of the present disclosure.

From the above description of the embodiments, it will be apparent to those skilled in the art that the present disclosure may be implemented by means of software and necessary general-purpose hardware, or may be implemented by hardware, but in many cases the former is more favorable. Based on this understanding, the substantial technical solutions provided by the present disclosure, or the part contributing to the prior art, may be embodied in the form of a software product. The software product is stored in a computer readable storage medium, such as a computer floppy disk, a read-only memory (ROM), a random access memory (RAM), a flash, a hard disk, an optical disk or the like, and includes several instructions for enabling a computer device (which may be a personal computer, a server, a network device or the like) to execute the method according to each embodiment of the present disclosure.

It is to be noted that units and modules included in the above-mentioned embodiment of the apparatus for calculating a transient overvoltage at a DC sending end by taking into account a dynamic process of a control system are just divided according to functional logic, and the division is not limited to this, as long as the corresponding functions may be implemented. In addition, the specific name of the each functional unit is just intended for distinguishing purposes, and is not to limit the scope of the present disclosure.

It is to be noted that the foregoing description merely depicts some exemplary embodiments of the present disclosure and the technical principles used therein. It will be understood by those skilled in the art that the present disclosure will not be limited to the specific embodiments described herein. Those skilled in the art can make various apparent modifications, adaptations and substitutions without departing from the scope of the present disclosure. Therefore, while the present disclosure has been described in detail through the above-mentioned embodiments, the present disclosure is not limited to the above-mentioned embodiments and may include more other equivalent embodiments without departing from the concept of the present disclosure. The scope of the present disclosure is determined by the scope of the appended claims.

What is claimed is:

1. A method for calculating a transient overvoltage at a direct current (DC) sending end by taking into account a dynamic process of a control system, comprising:
calculating a first reactive power consumed by a converter station based on system operation parameters and a DC closed-loop transfer function;
calculating a transient voltage change rate based on the first reactive power and a second reactive power on an alternating current (AC) side; and
iterating the transient voltage change rate to obtain a transient overvoltage.

2. The method of claim 1, wherein calculating the first reactive power consumed by the converter station based on the system operation parameters and the DC closed-loop transfer function comprises:
calculating a DC current of a DC line based on the system operation parameters and a preset DC closed-loop transfer function; and
determining the first reactive power consumed by the converter station based on the DC current.

3. The method of claim 2, wherein calculating the DC current of the DC line based on the system operation parameters and the preset DC closed-loop transfer function comprises:
determining an association relationship between a DC current, a DC setting current, a DC normal voltage, and a DC fault voltage according to the DC closed-loop transfer function; and
calculating the DC current of the DC line based on the DC setting current, the DC normal voltage, the DC fault voltage, and the association relationship.

4. The method of claim 2, wherein when a rectifier adopts a constant current control mode, the determining the first reactive power consumed by the converter station based on the DC current comprises:
calculating a commutation angle of the rectifier based on device parameters of a transformer;
determining an ideal unloaded first DC voltage of the DC line according to a first AC voltage on a secondary side of the transformer; and
obtaining the first reactive power consumed by the converter station based on the first DC voltage, the DC current of the DC line, the commutation angle of the rectifier, and a preset calculation formula.

5. The method of claim 2, further comprising the following operations prior to calculating the first reactive power consumed by the converter station based on the system operation parameters and the DC closed-loop transfer function:
in response to a rectifier adopting a constant current control mode, determining an open-loop transfer function of the rectifier;
in response to the rectifier adopting the constant current control mode while an inverter adopts a constant extinction angle control mode, determining an open-loop transfer function of the DC line; and
determining the DC closed-loop transfer function based on the open-loop transfer function of the rectifier and the open-loop transfer function of the DC line.

6. The method of claim 1, wherein calculating the transient voltage change rate based on the first reactive power and the second reactive power on the AC side comprises:
calculating a reactive power difference between the first reactive power and the second reactive power on the AC side; and
determining a quotient yielded from dividing the reactive power difference by a short-circuit capacity of the converter station as the transient voltage change rate.

7. The method of claim 1, wherein iterating the transient voltage change rate to obtain the transient overvoltage comprises:
adding the transient voltage change rate to a current commutation bus voltage to obtain a new commutation bus voltage, and updating the new commutation bus voltage as the current commutation bus voltage;
obtaining a new transient voltage change rate based on the new commutation bus voltage and a filter susceptance; and
updating the new transient voltage change rate as the transient voltage change rate, returning to perform the operation of determining a new commutation bus voltage until a maximum value of the second reactive power is equal to an actual value, and determining the updated transient voltage change rate as the transient overvoltage.

8. A device, comprising:
one or more processors; and
a memory, configured to store one or more programs;
wherein the one or more programs, when executed by the one or more processors, cause the one or more processors to perform a method for calculating a transient overvoltage at a direct current sending end by taking into account a dynamic process of a control system , the method comprising:
calculating a first reactive power consumed by a converter station based on system operation parameters and a DC closed-loop transfer function;
calculating a transient voltage change rate based on the first reactive power and a second reactive power on an alternating current (AC) side; and
iterating the transient voltage change rate to obtain a transient overvoltage.

9. The device of claim 8, wherein calculating the first reactive power consumed by the converter station based on the system operation parameters and the DC closed-loop transfer function comprises:
calculating a DC current of a DC line based on the system operation parameters and a preset DC closed-loop transfer function; and
determining the first reactive power consumed by the converter station based on the DC current.

10. The device of claim 9, wherein calculating the DC current of the DC line based on the system operation parameters and the preset DC closed-loop transfer function comprises:
determining an association relationship between a DC current, a DC setting current, a DC normal voltage, and a DC fault voltage according to the DC closed-loop transfer function; and
calculating the DC current of the DC line based on the DC setting current, the DC normal voltage, the DC fault voltage, and the association relationship.

11. The device of claim 9, wherein when a rectifier adopts a constant current control mode, the determining the first reactive power consumed by the converter station based on the DC current comprises:
calculating a commutation angle of the rectifier based on device parameters of a transformer;
determining an ideal unloaded first DC voltage of the DC line according to a first AC voltage on a secondary side of the transformer; and
obtaining the first reactive power consumed by the converter station based on the first DC voltage, the DC current of the DC line, the commutation angle of the rectifier, and a preset calculation formula.

12. The device of claim 9, wherein the method further comprises the following operations prior to calculating the first reactive power consumed by the converter station based on the system operation parameters and the DC closed-loop transfer function:
in response to a rectifier adopting a constant current control mode, determining an open-loop transfer function of the rectifier;
in response to the rectifier adopting the constant current control mode while an inverter adopts a constant extinction angle control mode, determining an open-loop transfer function of the DC line; and
determining the DC closed-loop transfer function based on the open-loop transfer function of the rectifier and the open-loop transfer function of the DC line.

13. The device of claim 8, wherein calculating the transient voltage change rate based on the first reactive power and the second reactive power on the AC side comprises:
calculating a reactive power difference between the first reactive power and the second reactive power on the AC side; and
determining a quotient yielded from dividing the reactive power difference by a short-circuit capacity of the converter station as the transient voltage change rate.

14. The device of claim 8, wherein iterating the transient voltage change rate to obtain the transient overvoltage comprises:
adding the transient voltage change rate to a current commutation bus voltage to obtain a new commutation bus voltage, and updating the new commutation bus voltage as the current commutation bus voltage;
obtaining a new transient voltage change rate based on the new commutation bus voltage and a filter susceptance; and
updating the new transient voltage change rate as the transient voltage change rate, returning to perform the operation of determining a new commutation bus voltage until a maximum value of the second reactive power is equal to an actual value, and determining the updated transient voltage change rate as the transient overvoltage.

15. A computer-readable storage medium configured to store computer programs which, when executed by a processor, perform a method for calculating a transient overvoltage at a direct current sending end by taking into account a dynamic process of a control system , the method comprising:
calculating a first reactive power consumed by a converter station based on system operation parameters and a DC closed-loop transfer function;
calculating a transient voltage change rate based on the first reactive power and a second reactive power on an alternating current (AC) side; and
iterating the transient voltage change rate to obtain a transient overvoltage.

16. The computer-readable storage medium of claim 15, wherein calculating the first reactive power consumed by the converter station based on the system operation parameters and the DC closed-loop transfer function comprises:
calculating a DC current of a DC line based on the system operation parameters and a preset DC closed-loop transfer function; and
determining the first reactive power consumed by the converter station based on the DC current.

17. The computer-readable storage medium of claim 16, wherein calculating the DC current of the DC line based on the system operation parameters and the preset DC closed-loop transfer function comprises:
determining an association relationship between a DC current, a DC setting current, a DC normal voltage, and a DC fault voltage according to the DC closed-loop transfer function; and
calculating the DC current of the DC line based on the DC setting current, the DC normal voltage, the DC fault voltage, and the association relationship.

18. The computer-readable storage medium of claim 16, wherein when a rectifier adopts a constant current control mode, the determining the first reactive power consumed by the converter station based on the DC current comprises:
calculating a commutation angle of the rectifier based on device parameters of a transformer;
determining an ideal unloaded first DC voltage of the DC line according to a first AC voltage on a secondary side of the transformer; and
obtaining the first reactive power consumed by the converter station based on the first DC voltage, the DC current of the DC line, the commutation angle of the rectifier, and a preset calculation formula.

19. The computer-readable storage medium of claim 16, wherein the method further comprises the following operations prior to calculating the first reactive power consumed by the converter station based on the system operation parameters and the DC closed-loop transfer function:
in response to a rectifier adopting a constant current control mode, determining an open-loop transfer function of the rectifier;
in response to the rectifier adopting the constant current control mode while an inverter adopts a constant extinction angle control mode, determining an open-loop transfer function of the DC line; and
determining the DC closed-loop transfer function based on the open-loop transfer function of the rectifier and the open-loop transfer function of the DC line.

20. The computer-readable storage medium of claim 15, wherein calculating the transient voltage change rate based on the first reactive power and the second reactive power on the AC side comprises:
calculating a reactive power difference between the first reactive power and the second reactive power on the AC side; and
determining a quotient yielded from dividing the reactive power difference by a short-circuit capacity of the converter station as the transient voltage change rate.
